(19) United States
(12) Patent Application Publication
(10) Pub. No.: US 2011/0155450 A1
(43) Pub. Date: Jun. 30, 2011

(54) PRINTED CIRCUIT BOARD AND ELECTRONIC APPARATUS

(76) Inventors: Daigo Suzuki, Kanagawa (JP); Terunari Kanou, Tokyo (JP)

(21) Appl. No.: 12/955,708

(22) Filed: Nov. 29, 2010

(30) Foreign Application Priority Data
Dec. 25, 2009 (JP) JP 2009-294250

(51) Int. Cl. H05K 5/00; H05K 1/11

(52) U.S. Cl. 174/520; 174/263

(57) ABSTRACT

According to one embodiment, a printed circuit board is provided. The printed circuit board includes a wiring board, an insertion mount device having lead terminals, and a flexible insulator. The wiring board has a first surface, a second surface on a side opposite the first surface, and through holes. The insertion mount device is mounted on the first surface of the wiring board such that the lead terminals are inserted into the through holes and are soldered to the through holes. At least one of the lead terminals has a distal end protruding out from a corresponding one of the through holes. The insulator provided on the second surface to cover the distal end of the at least one of the lead terminals.

### CROSS-REFERENCE TO RELATED APPLICATION(S)

This application is based upon and claims the benefit of priority from Japanese Patent Application No. 2009-294250 filed on Dec. 25, 2009, the entire contents of which is incorporated herein by reference.

### FIELD

Embodiments described herein relate generally to a printed circuit board and an electronic apparatus.

### BACKGROUND

A related art printed circuit board is used in an electronic apparatus such as a portable computer and has insertion mount devices mounted on a single wiring board. An insertion mount device is, for example, a connector and has lead terminals.

The wiring board of the related art printed circuit board has a first surface, a second surface on a side opposite the first surface, and through holes opened at the first and second surfaces. An inner face of each of the through holes is coated with a conductive plating layer. For each of the through holes, lands are formed on the first and second surfaces of the wiring board to surround respective open ends of the through hole such that the lands are electrically connected to the plating layer.

The insertion mount device is mounted on the first or second surface of the wiring board such that the lead terminals are inserted into corresponding ones of the through holes and soldered to the through holes. The printed circuit board may also have a surface mount device that is soldered onto the land on a side opposite the insertion mount device.

The lead terminals inserted into the through holes may protrude out from the wiring board. When arranging such a printed circuit board in an electronic apparatus, an insulator is provided between distal ends of the lead terminals of the printed circuit board and other parts of the electronic apparatus for electrical insulation.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the invention;

FIG. 2 is an exemplary sectional view of the portable computer according to the first embodiment of the invention;

FIG. 3 is an exemplary sectional view of a printed circuit board according to the first embodiment of the invention;

FIG. 4 is an exemplary sectional view of a wiring board of the printed circuit board according to the first embodiment of the invention, illustrating a solder paste provided on a first surface of the wiring board and a mounting of a surface mount device on the solder paste;

FIG. 5 is another exemplary sectional view of the wiring board, illustrating the surface mount device reflow-soldered onto the first surface of the wiring board in the first embodiment of the invention;

FIG. 6 is yet another exemplary sectional view of the wiring board, illustrating a solder paste provided on a second surface of the wiring board in the first embodiment of the invention;

FIG. 7 is yet another exemplary sectional view of the wiring board, illustrating an insertion of lead terminals of an insertion mount device into through holes in which the solder paste is provided in the first embodiment of the invention;

FIG. 8 is an exemplary sectional view of a wiring board, illustrating a solder paste provided in through holes of the wiring board and an adhesive agent provided on a insulating layer on a first surface of the wiring board in a second embodiment of the invention;

FIG. 9 is an exemplary sectional view of a printed circuit board according to the second embodiment of the invention, illustrating an insertion mount device mounted on a second surface of the wiring board; and

FIG. 10 is an exemplary sectional view of a printed circuit board according to a modification of the second embodiment of the invention. illustrating an insertion mount device mounted on the second surface of the wiring board.

### DETAILED DESCRIPTION

Various embodiments according to the invention will be described hereinafter with reference to the accompanying drawings.

In general, according to one embodiment of the invention, a printed circuit board is provided. The printed circuit board includes a wiring board, an insertion mount device having lead terminals, and a flexible insulator. The wiring board has a first surface, a second surface on a side opposite the first surface, and through holes. The insertion mount device is mounted on the first surface of the wiring board such that the lead terminals are inserted into the through holes and are soldered to the through holes. At least one of the lead terminals has a distal end protruding out from a corresponding one of the through holes. The insulator provided on the second surface to cover the distal end of the at least one of the lead terminals.

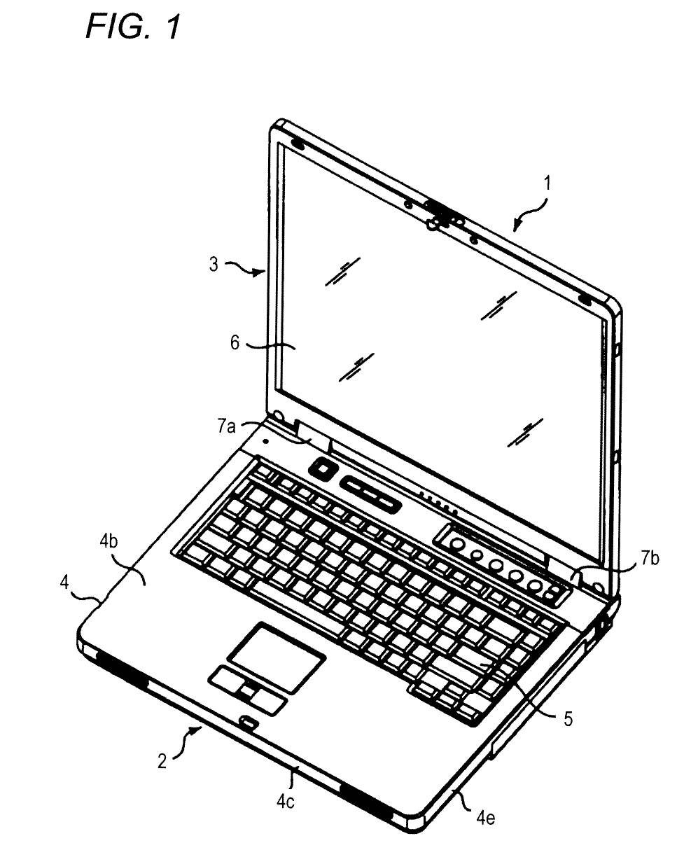

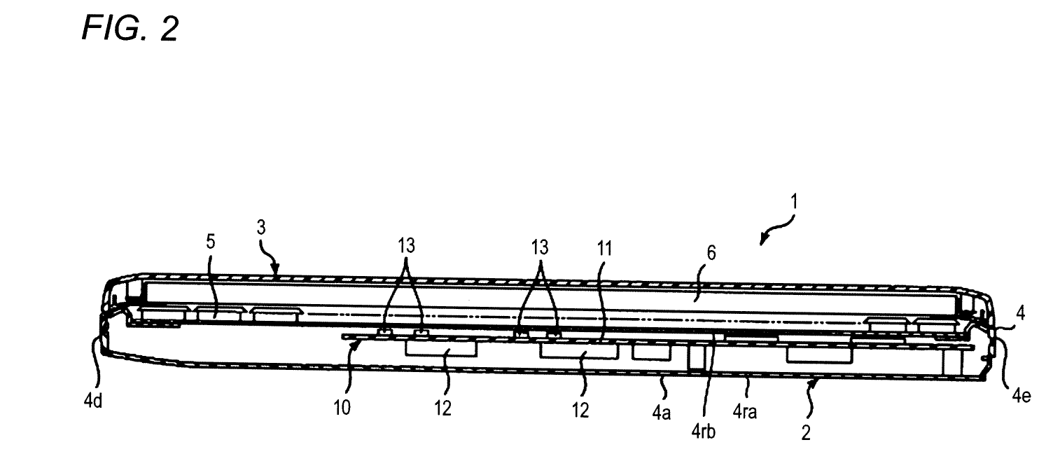

FIGS. 1 and 2 illustrate a portable computer 1 as an example of an electronic apparatus according to one embodiment of the invention. The portable computer 1 has a body unit 2, and a display unit 3. The body unit 2 has a housing 4. The housing 4 is shaped like a flat box having a bottom wall 4a. a top wall 4b, a front wall 4c, left and right side walls 4d and 4e, and a rear wall which is not shown. Each of the walls of the housing 4 has an inner wall portion facing the inside of the housing 4. The top wall 4b of the housing 4 supports a keyboard 5.

The display unit 3 has a liquid crystal display panel 6. The display unit 3 is supported on a rear end portion of the housing 4 through a pair of hinge portions 7a, 7b. The display unit 3 is rotatable between a close position in which the display unit 3 is laid on the housing 4 such that the keyboard 5 is covered by the display unit 3 from above and an open position in which the display unit 3 stands up such that the keyboard 5 is exposed.

As shown in FIG. 2, a printed circuit board 10 is accommodated inside the housing 4. The printed circuit board 10 has a printed wiring board 11. insertion mount devices 12, and surface mount devices 13.

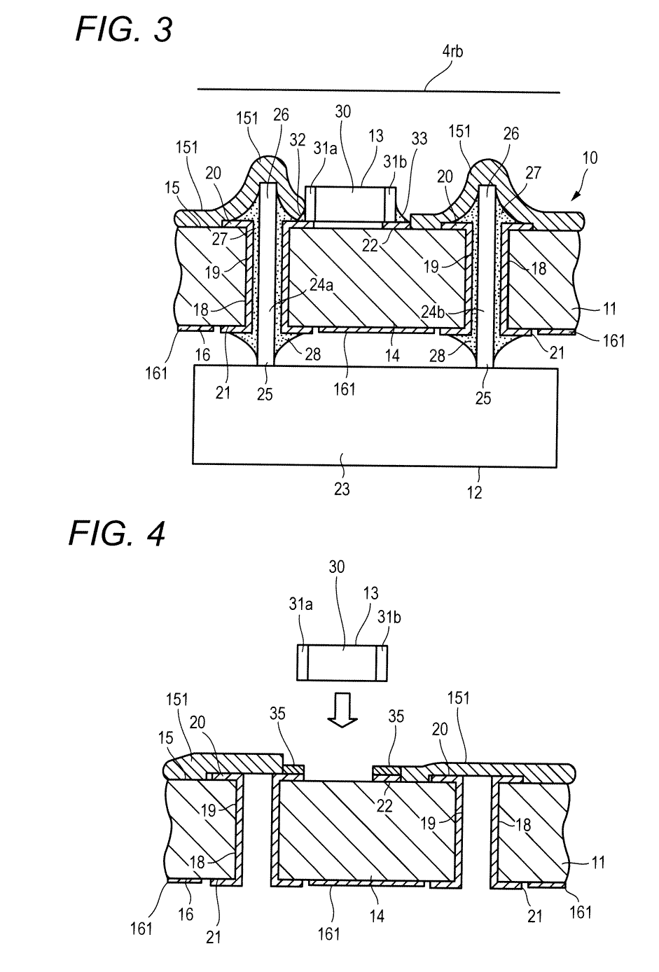

As shown in FIG. 3, the printed wiring board 11 includes an insulating substrate 14 on which conductor patterns are formed. The insulating substrate 14 has a first surface 15, and a second surface 16 on a side opposite the first surface 15. The insulating substrate 14 is arranged such that the first surface 15 faces an inner wall portion 4rb of the top wall 4b and the second surface 16 faces an inner wall portion 4ra of the bottom wall 4a. The printed wiring board 11 in this embodiment is a double-sided printed wiring board having the conductor patterns on the first and second surfaces 15, 16 of the insulating substrate 14 respectively, and is supported by the bottom wall 4a of the housing 4. The printed wiring board 11 is not particularly limited to the double-sided printed wiring board. For example, a multilayer printed wiring board having further conductor patterns inside the insulating substrate 14 may be used as the printed wiring board 11.

The insulating substrate 14 in this embodiment has flexible solder resist layers 151 on a side of the first surface 15. For example, the solder resist layers 151 are made of an insulating and flexible material. The insulating substrate 14 in this embodiment further has a thermosetting resist layer 161 provided on the second surface 16.

Through holes 18 are formed in the printed wiring board 11. The through holes 18 are formed through the insulating substrate 14 in a direction of a thickness of the insulating substrate 14 so as to be opened at the first and second surfaces 15, 16. An inner face of each of the through holes 18 is covered with a conductive plating layer 19.

Lands 20 are formed on the first surface 15 of the insulating substrate 14. Similarly. lands 21 are formed on the second surface 16 of the insulating substrate 14. Each of the lands 20, 21 forms a part of the conductor patterns, and is shaped like a ring that surrounds an open end of corresponding one of the through holes 18. The lands 20, 21 are electrically connected to the plating layer 19 of the corresponding through holes 18 respectively.

Pads 22 are provided on the first surface 15 of the insulating substrate 14. Each of the pads 22 is electrically connected to corresponding one of the conductor patterns and is disposed near one of the lands 20.

An insertion mount device 12 is, for example, a connector to which a large force is applied at a portion that is joined to the printed wiring board 11. The insertion mount device 12 has a body 23, and a pair of lead terminals 24a, 24b which protrude from the body 23. The lead terminals 24a, 24b are arranged parallel to each other at a distance. Each of the lead terminals 24a, 24b has a base end 25 adjacent to the body 23, and a distal end 26. When the insertion mount device 12 is mounted on the printed wiring board 11, the distal end 26 is located on a side of the printed wiring board 11 opposite the body 23.

The lead terminals 24a, 24b of the insertion mount device 12 are inserted into adjacent ones of the through holes 18 in the printed wiring board 11 in a direction from the second surface 16 toward the first surface 15. The insertion mount device 12 is mounted on the second surface 16 of the printed wiring board 11 by reflow-soldering the lead terminals 24a, 24b to the through holes 18.

When the insertion mount device 12 is mounted on the second surface 16, gaps between the lead terminals 24a, 24b and the plating layers 19 of the through holes 18 are filled with solder 27, and the base ends 25 of the lead terminals 24a, 24b protrude from the second surface 16 of the printed wiring board 11. Solder fillets 28 are formed between the base ends 25 and the lands 21 on the second surface 16.

Further, the distal ends 26 of the lead terminals 24a, 24b are disposed outside the through holes 18 and protrude from the first surface 15 of the printed wiring board 11. That is, the lead terminals 24a, 24b are soldered to the through holes 18 such that they extend through the through holes 18 respectively.

The distal ends 26 of the lead terminals 24a, 24b protruding from the first surface 15 are covered with solder resist layers 151 respectively. While the distal ends 26 of the lead terminals 24a, 24b abut the solder resist layers 151 respectively in this example, the distal ends 26 of the lead terminals 24a, 24b may be separated from the solder resister layers 151 respectively by, for example, the solder 27.

According to the printed wiring board 11 having the configuration described above, it is possible to prevent the distal ends 26 of the lead terminals 24a, 24b protruding from the first surface 15 of the printed wiring board 11 from contacting the inner wall portion 4rb of the top wall 4b, which may otherwise cause a short-circuit. Further, because the distal ends 26 of the lead terminals 24a, 24b are covered with the solder resist layers 151, it is not necessary to provide a separate insulating member between the printed wiring board 11 and the inner wall portion 4rb of the top wall 4b of the housing 4. Accordingly, the number of components can be reduced.

A surface mount device 13 is, for example, a chip capacitor which is lighter in weight and smaller in shape than the insertion mount device 12. The surface mount device 13 has a body 30, and first and second electrodes 31a, 31b. The first electrode 31a is disposed on one end of the body 30 and the second electrode 31b is disposed on the other end of the body 30.

The first electrode 31a of the surface mount device 13 is reflow-soldered to a land 20 corresponding to the through hole 18 into which one of the lead terminals 24a is inserted. The first electrode 31a is provided near an open end of the through hole 18 on the first surface 15. A solder fillet 32 is formed between the first electrode 31a and the land 20.

The second electrode 31b of the surface mount device 13 is reflow-soldered to a pad 22. A solder fillet 33 is formed between the second electrode 31b and the pad 22.

As shown in FIG. 3, when the insertion mount device 12 and the surface mount device 13 are mounted on the printed wiring board 11, the distal ends 26 of the lead terminals 24a is spaced apart from the first electrode 31a of the surface mount device 13. A gap between the distal end 26 of the lead terminal 24a and the first electrode 31a is filled with the solder 27.

Next, a method of manufacturing the printed circuit board 10 will be described further with reference to FIGS. 4 to 7.

First, a printed wiring board 11 having pads 22 and through holes 18 coated with plating layers 19 is provided. The printed wiring board 11 is held such that the first surface 15 of the printed wiring board 11 faces upward. A flexible resist film is printed on the first surface 15 of the printed wiring board 11 in advance. A thermosetting resist film 161 is printed on the second surface 16 of the printed wiring board 11 in advance. In this condition, a solder paste is printed on the lands 20 and the pads 22 on the first surface 15 of the printed wiring board 11.

A screen mask is used when printing the solder paste and the resist film. The screen mask has openings in positions corresponding to the lands 20 and the pads 22. The screen mask is laid onto the first surface 15 of the printed wiring board 11 at the time of printing the solder paste. The solder paste is pressed into the opening portions of the screen mask using a squeegee, and is printed onto the lands 20 and the pads 22.

In this manner, as shown in FIG. 4, the solder paste is provided on the lands 20 and the pads 22 on the first surface 15. so that surfaces of the lands 20 and the pads 22 are covered with solder layers 35.

Then, the surface mount device 13 is provided onto the first surface 15 of the printed wiring board 11 using, for example, a surface mounter, so that first and second electrodes 31a, 31b of the surface component 13 are placed on the corresponding land 20 and pad 22. The first electrode 31a is located near the through holes 18.

Subsequently, the printed wiring board 11 is placed inside a reflow furnace and is heated in the reflow furnace. The solder layers 35 are melted by this heating, so that a gap between the first electrode 31a and the land 20 and a gap between each second electrode 31b and the pad 22 are filled with molten solder. A part of the molten solder is further spread into the open end of the through hole 18 from the first electrode 31a.

Thereafter, the printed wiring board 11 is taken out from the reflow furnace and cooled to harden the molten solder. Consequently, as shown in

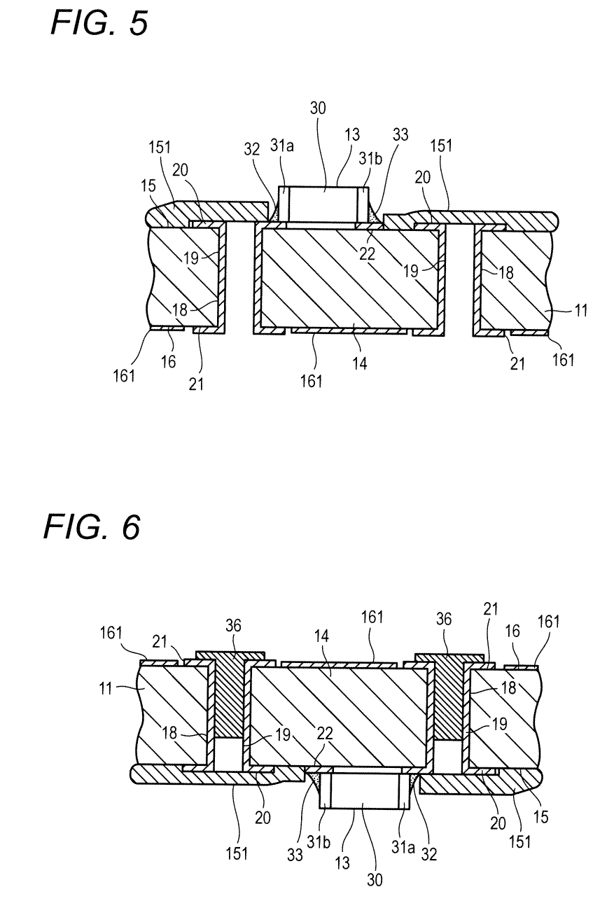

FIG. 5. the solder fillet 32 is formed between the first electrode 31a and the land 20, and the solder fillet 33 is formed between the second electrode 31b and the pad 22. Accordingly, the first and second electrodes 31a, 31b are electrically and mechanically connected to the lands 20 and the pads 22, whereby mounting of the surface mount devices 13 on the first surface 15 is completed.

Next, as shown in FIG. 6, the printed wiring board 11 is turned upside down so that the second surface 16 faces upward. In this state, a solder paste is printed on lands 21 on the second surface 16 using a screen mask and a squeegee. In this manner, the solder paste is provided to the lands 21 and the through holes 18 such that the lands 21 are covered with solder layers 36 and the through holes 18 are filled with the solder layers 36 respectively.

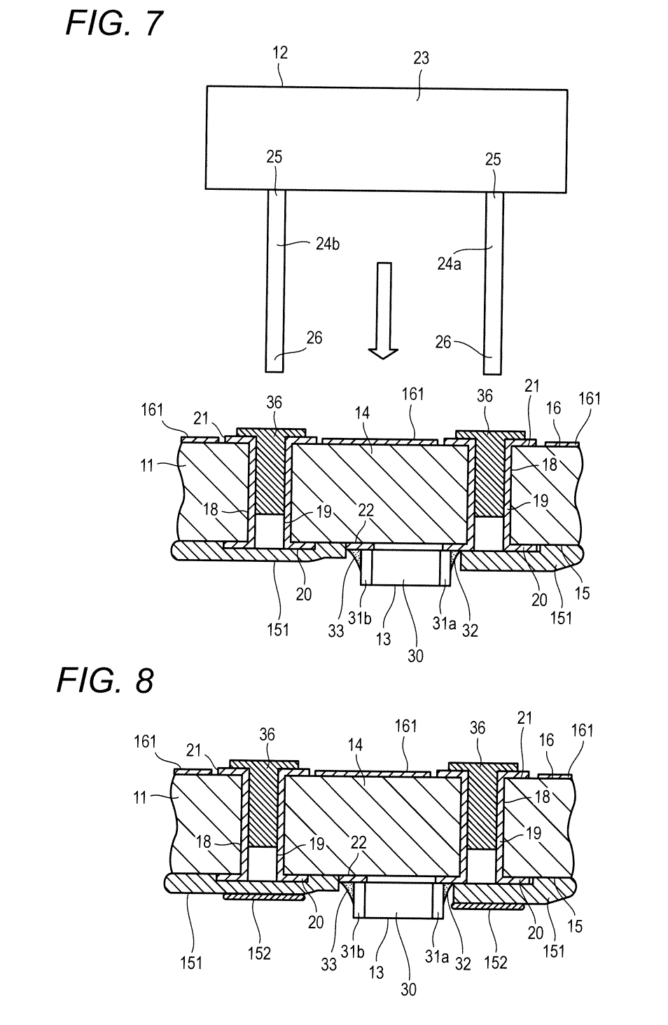

After providing the solder paste, as shown in FIG. 7, the lead terminals 24a, 24b of the insertion mount device 12 are inserted into the through holes 18 that are filled with the solder paste in a direction from the second surface 16 toward the first surface 15. The distal ends 26 of the lead terminals 24a, 24b protrude from the first surface 15 and are located outside the through holes 18. Each of the distal ends 26 of the lead terminals 24a, 24b abuts the solder resist layer 151 and deforms the solder resist layer 151 toward the outside of the through hole 18.

Then, the printed wiring board 11 is placed inside the reflow furnace and heated in the reflow furnace again. The solder layers 36 are melted by this heating, so that a gap between each the of the lead terminals 24a, 24b and the corresponding plating layer 19 and a gap between the distal end 26 of the lead terminal 24a and the first electrode 31a of the surface mount device 13 are filled with molten solder.

Subsequently, the printed wiring board 11 is taken out from the reflow furnace and cooled to harden the molten solder. Consequently, as shown in FIG. 3, solder fillets 28 are formed between the base end 25 of each the lead terminals 24a, 24b and the lands 21, respectively, and a gap between the distal end 26 of the lead terminal 24a and the first electrode 31a of the surface mount devices 13 is filled with the solder 27. Accordingly, the lead terminals 24a, 24b of the insertion mount device 12 are electrically and mechanically connected to corresponding ones of the through holes 18 respectively, whereby mounting of the insertion mount device 12 on the second surface 16 is completed.

According to the first embodiment, when the insertion mount device 12 is mounted on the second surface 16 of the printed wiring board 11, the distal ends 26 of the lead terminals 24a, 24b of the insertion mount device 12 protrude from the first surface 15 of the printed wiring board 11 and stay outside corresponding ones of the through holes 18. Each of the distal ends 26 of the lead terminals 24a, 24b abuts on the solder resist layer 151 and deforms the solder resist layer 151 toward the outside of the corresponding through hole 18.

Therefore, contact between the distal ends 26 of the lead terminals 24a, 24b and the inner wall portion of the housing 4 can be avoided. Accordingly, it is not necessary to provide a separate insulator between the first surface 15 of the printed wiring board 11 and the inner wall portion of the housing 4, whereby the number of components can be reduced and the manufacturing process can be simplified. Moreover, in this embodiment, because the solder resist layer 151 is provided by printing, displacement of the solder resist layer 151 is prevented.

Further, because the insertion mount device 12 and the surface mount device 13 can be mounted opposite to each other on respective sides of the through holes 18, it is advantageous in that high-density mounting is achieved.

In addition, because a gap between the distal end 26 of the lead terminal 24a and the corresponding solder resist layer 151 is filled with solder 27, a cavity is hardly created inside the through hole 18 when the insertion mount devices 12 and the surface mount devices 13 are soldered to the printed wiring board 11. Consequently, for example, even when temperature of the printed circuit board 10 rises, the solder 27 is prevented from being peeled off due to expansion of air inside the through holes 18. As a result, reliability on electrical connection between the printed wiring board 11 and the insertion mount device 12 is improved.

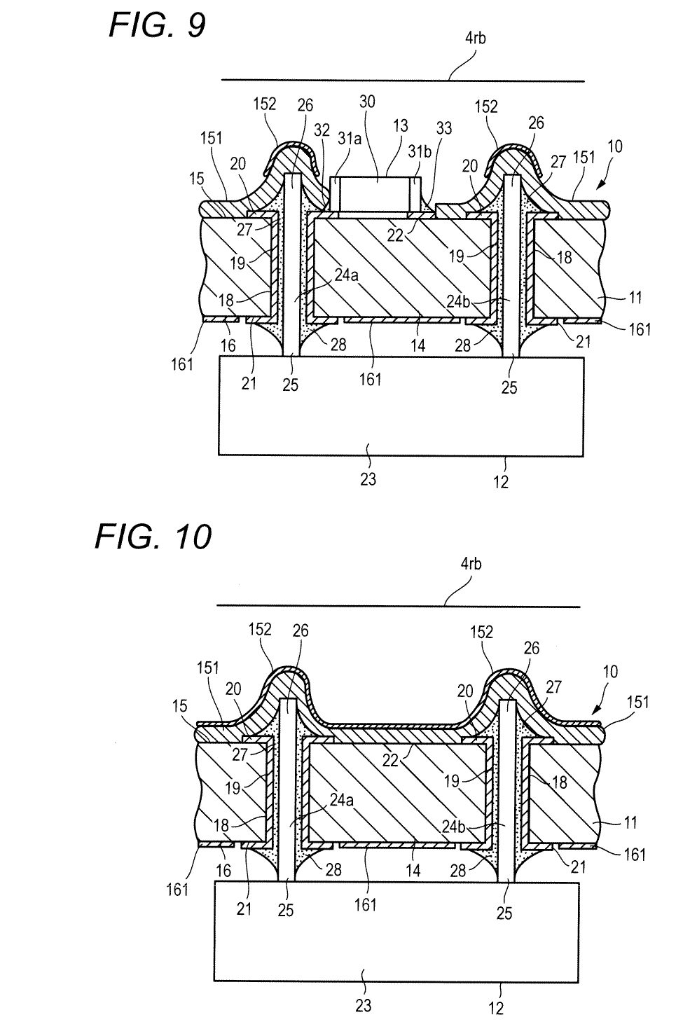

FIGS. 8 and 9 show a second embodiment of the invention. The second embodiment is different from the first embodiment in that protectors 152 are provided on surfaces of the solder resist layers 151 on a side to which the distal ends 26 of the lead terminals 24a, 24b are not in contact.

As shown in FIG. 8, in the second embodiment of the invention, the printed wiring board 11 firstly held such that the second surface 16 of the printed wiring board 11 faces upward. A solder paste is printed on the lands 20 on the first surface 15 using a screen mask and a squeegee, whereby the solder paste is provided on the lands 20 and into the through holes 18. Accordingly, the lands 20 are covered with solder layers 36, and the through holes 18 are filled with the solder layers 36 respectively.

After providing the solder paste, the protectors 152 are applied on portions of the solder resist layer 151 on the second surface 16 of the printed wiring board 11 where the distal ends 26 of the lead terminals 24a, 24b of the insertion mount device 12 face, i.e. portions with which open ends of the through holes 18 are covered. The protectors 152 include, for example, a thermosetting adhesive.

Then, as shown in FIG. 9, the lead terminals 24a, 24b of the insertion mount device 12 are inserted into the through holes 18 filled with the solder paste, in a direction from the second surface 16 to the first surface 15, such that the distal ends 26 of the lead terminals 24a, 24b protrude from the first surface 15 and are disposed outside the through holes 18.

Each of the distal ends 26 of the lead terminals 24a, 24b abuts on the solder resist layer 151 and deforms the solder resist layer 151 and the protector 152 toward the outside of the corresponding through hole 18.

Subsequently, the printed wiring board 11 is placed inside a reflow furnace and heated in the reflow furnace. The solder layers 36 are melted, so that a gap between the lead terminals 24a, 24b and the plating layers 19 and a gap between the base ends 25 of the lead terminals 24a, 24b and the lands 21 are filled with molten solder. In addition, the protectors 152 are hardened to protect the respective solder resist layers 151.

Then, the printed wiring board 11 is taken out from the reflow furnace and cooled to harden the molten solder. Consequently, as shown in FIG. 9, solder fillets 28 are formed between the base ends 25 of the lead terminals 24a, 24b and the lands 21 respectively so that the lead terminals 24a, 24b of the insertion mount device 12 are electrically and mechanically connected to the corresponding through holes 18, whereby the mounting of the insertion mount device 12 on the second surface 16 is completed.

Also in the second embodiment, the lead terminals 24a, 24b of the insertion mount device 12 protrude from the through holes 18. However, each of the distal ends 26 of the lead terminals 24a, 24b abuts on the solder resist layer 151 and deforms the solder resist layer 151 toward the outside of the corresponding through hole 18.

Therefore, contact between each of the distal ends 26 of the lead terminals 24a, 24b and the inner wall portion of the housing 4 can be avoided. Accordingly, it is not necessary to provide a separate insulator between the first surface 15 of the printed wiring board 11 and the inner wall portion of the housing 4, so that the number of components can be reduced.

Further, in the second embodiment, because the protectors 152 protect the solder resist layers 151 respectively, the solder resist layers 151 are prevented from being worn or crushed between the distal ends 26 of the lead terminals 24a, 24b and the inner wall of the housing 4.

FIG. 10 illustrates a modification of the second embodiment of the invention. In the modification of the second embodiment, a protector 152 is provided over the entire surface of the solder resist layer 151.

This configuration can obtain the same effect as in the second embodiment of the invention. Moreover, because the protector 152 can be applied at once, the manufacturing process is simplified.

In implementing the invention, the surface mount device is not limited to a chip capacitor. For example, the surface mount device may be other kinds of chip component or a small outline package (SOP). Likewise, the insertion mount device is not limited to a socket. For example, the insertion mount device may be a PGA semiconductor package.

In addition, the electronic apparatus according to the invention is not limited to a portable computer, and may be, for example, a personal digital assistant (PDA).

While certain embodiments have been described, these embodiments have presented by way of example only, and are not intended to limit the scope of the invention. Indeed, the novel structures and apparatuses described herein may be embodied in variety of other forms; furthermore, various omissions, substitutions and changes in the form of the structures and apparatuses described herein may be made without departing of the spirit of the invention. The accompanying claims and their equivalents are intended to cover such forms or modifications as would fall within the scope and spirit of the invention.

What is claimed is:

1. A printed circuit board comprising:
a wiring board comprising a first surface, a second surface on a side opposite the first surface, and through holes;
an insertion mount device comprising lead terminals, wherein the insertion mount device is mounted on the first surface of the wiring board such that the lead terminals are inserted into the through holes and are soldered to the through holes, wherein at least one of the lead terminals comprises a distal end protruding out from a corresponding one of the through holes; and
a flexible insulator provided on the second surface to cover the distal end of the at least one of the lead terminals.

2. The printed circuit board of claim 1, wherein the insulator comprises an insulating resist layer provided on the second surface.

3. The printed circuit board of claim 2, wherein the distal end of the at least one of the lead terminals abuts the insulator.

4. The printed circuit board of claim 3 further comprising a protector provided on a surface of the insulator on a side opposite a surface facing the distal end of the at least one of the lead terminals.

5. The printed circuit board of claim 4, wherein the distal end of each of the lead terminals protrudes out from the corresponding one of the through holes, and the protector is provided to cover the distal end of each of the lead terminals respectively.

6. An electronic apparatus comprising:
a housing;
a wiring board comprising a first surface, a second surface on a side opposite the first surface, and through holes, and wherein the wiring board is accommodated inside the housing;
an insertion mount device comprising lead terminals, wherein the insertion mount device is mounted on the first surface of the wiring board such that the lead terminals are inserted into the through holes and soldered to the through holes; and
a flexible insulator provided on the second surface such that the insulator faces the distal end of at least one of the lead terminals.

7. The apparatus of claim 6, wherein the distal end of at least one of the lead terminals is protruded outs from a corresponding one of the through holes.

8. The apparatus of claim 7, wherein the insulator comprises an insulating resist layer provided on the second surface.

9. The apparatus of claim 8, wherein the distal end of at least one of the lead terminals abuts the insulator.

10. The apparatus of claim 9. wherein a surface of the insulator on a side opposite a surface facing the distal end of at least one of the lead terminals faces a wall portion of the housing.
